(19) United States
(12) Patent Application Publication
(10) Pub. No.: US 2025/0036512 A1
(43) Pub. Date: Jan. 30, 2025

(54) Method and Device for Product Fault Root Cause Analysis Based on Knowledge Graphs

(71) Applicant: Robert Bosch GmbH, Stuttgart (DE)

(72) Inventors: Yuxiao Li, Shanghai (CN); Qiushi Cao, Shanghai (CN); Irlan Grangel Gonzalez, Shanghai (CN); Wei Huang, Shanghai (CN)

(21) Appl. No.: 18/769,669

(22) Filed: Jul. 11, 2024

(30) Foreign Application Priority Data
Jul. 26, 2023 (CN) 2023 1093 0337.1

(51) Int. Cl. G06F 11/07

(52) U.S. Cl. CPC G06F 11/079

(57) ABSTRACT

A method for product fault root cause analysis based on knowledge graphs includes (i) acquiring product-associated design data, wherein the design data comprises semi-structured data and/or unstructured data, (ii) acquiring product-associated production data, wherein the production data comprises structured data, (iii) performing information extraction on the design data to acquire structured design data, (iv) performing a knowledge fusion of knowledge generated separately based on the production data and the structured design data to construct a target knowledge graph, and (v) and performing product fault root cause analysis tasks based on the target knowledge graph.

This application claims priority under 35 U.S.C. § 119 to patent application no. CN 2023 1093 0337.1, filed on Jul. 26, 2023 in China, the disclosure of which is incorporated herein by reference in its entirety.

Generally speaking, the present disclosure relates to the field of knowledge graphs, and more specifically, to a method and device for product fault root cause analysis based on knowledge graphs.

### BACKGROUND

In the field of production and manufacturing, it is necessary to control the production process in order to ensure production capacity while improving product quality and reducing product failure rates. Therefore, when there is a product fault issue on the production line, it is necessary to trace and find the problem node as soon as possible to ensure subsequent production efficiency. In the traditional era of manufacturing, product fault root cause analysis generally relied on expert experience and was conducted manually. However, with the continuous development of manufacturing systems and processes, the potential fault nodes and generation paths involved in products have becoming increasingly complex, making it difficult to manually find the cause of a fault in a short period of time.

Since entering the era of intelligent manufacturing, attempts have been made to solve the product fault root cause analysis in an intelligent manner, of which, the use of knowledge maps has attracted considerable attention. Knowledge graphs are structured, machine-readable semantic knowledge bases that aid in knowledge modeling, data integration, and standardization, providing extended functionalities including data access and querying. Currently, knowledge graphs are generally built based on data from the production system, such as data from the MES and SAP system. Therefore, product fault root cause analysis is primarily based on relevant knowledge from the production side.

However, in actual production and manufacturing, product faults may originate not only from the production side, but also from the design side. Data from the production side is generally structured and stored in relational databases such as Oracle, Impala, etc. However, raw data from the design side is typically semi-structured or unstructured, with barriers between heterogeneous data sources, making it difficult for computers to process and analyze directly. An improved scheme for building knowledge graphs based on multi-source heterogeneous data is therefore needed to enable deeper and comprehensive product fault root cause analysis.

### SUMMARY

In production and manufacturing, product fault root cause analysis needs to be conducted when there are product fault issues on the production line. Considering that the field of intelligent manufacturing is generally knowledge-intensive, it is advantageous to introduce knowledge graph techniques to perform product fault root cause analysis in the field of intelligent manufacturing. Knowledge graphs are structured semantic networks that provide the ability to powerfully organize, manage, and understand vast amounts of information. Specifically, entities, entity relationships, and entity attributes extracted from existing data/original data are used to form networks to construct knowledge graphs, and the semantics contained in the knowledge graphs are utilized for inference to acquire potential fault occurrence paths and further quantify the probability of fault root causes.

It is desirable to provide a method and device for product fault root cause analysis based on knowledge graphs. They are capable of acquiring entities, entity relationships, and entity attributes based on multi-source heterogeneous data from all aspects from design to production, and use the acquired entities, entity relationships and entity attributes to construct knowledge graphs, to avoid the issue of solely relying on the production side and failing to comprehensively identify the causes of faults when conducting product fault root cause analysis based on knowledge graphs. Therefore, instead of building knowledge graphs based only on data from the production system, knowledge graphs can be further constructed based on data from the design side, expert experience, etc., and the inferential capabilities of knowledge graphs can be advantageously utilized to infer complete and deep potential fault occurrence paths in the event of product faults.

According to one aspect of the present disclosure, a method of performing a product fault root cause analysis based on knowledge graphs is provided, comprising: acquiring product-associated design data, wherein the design data comprises semi-structured data and/or unstructured data; acquiring product-associated production data, wherein the production data comprises structured data; performing information extraction on the design data to acquire structured design data; performing a knowledge fusion of knowledge generated separately based on the production data and the structured design data to construct a target knowledge graph; and performing product fault root cause analysis tasks based on the target knowledge graph.

According to another aspect of the present disclosure a system for performing product fault root cause analysis based on knowledge graphs is provided, comprising: a memory; a processor which is coupled to the memory, with the processor configured to cause one or more units to execute the method according to any one of the various examples of the present disclosure.

According to yet another aspect of the present disclosure, a computer-readable medium is provided storing a computer program comprising instructions, that, when executed by the processor, cause one or more units to execute the method according to various examples of the present disclosure.

### BRIEF DESCRIPTION OF THE DRAWINGS

The various examples of the subject matter for which protection is claimed will now be described by way of example with reference to the accompanying drawings. The same reference numerals are used in different accompanying drawings to denote the same or similar components.

FIG. 1 shows a module and data flow diagram for product fault root cause analysis conducted based on a knowledge graph according to one example of the present disclosure.

FIG. 2 shows an exemplary product component design drawing according to one example of the present disclosure.

FIG. 3 shows a causal chain diagram for product fault root cause analysis using a constructed knowledge graph according to one example of the present disclosure.

FIG. 4 shows a flowchart for product fault root cause analysis conducted based on a knowledge graph according to one example of the present disclosure.

FIG. 5 shows a block diagram of a device capable of conducting product fault root cause analysis based on a knowledge graph according to one example of the present disclosure.

### DETAILED DESCRIPTION

In the following description, numerous specific details are set forth to provide a thorough understanding of the examples of the present disclosure. However, those skilled in the relevant art will recognize that the present disclosure can be practiced without one or more of the specific details, or by using alternative methods, components, etc. In some instances, well-known structures and operations are not shown or described in detail to avoid unnecessarily obscuring the present disclosure.

In the field of production and manufacturing, when there is a product fault issue on the production line, it is crucial to trace and find the problem node as soon as possible to ensure subsequent production efficiency. With the development of various intelligent manufacturing technologies, there has been a gradual shift away from the analysis and identification of root causes of product faults by technical personnel to conducting product fault root cause analysis by utilizing information extracted from vast amounts of data by computer to assist in decision-making. Knowledge graphs can organize data from different sources into a network using entities, entity relationships, and entity attributes. They are a human-readable and machine-friendly knowledge representation, and their knowledge integration and inferential capabilities have been widely applied in product fault root cause analysis tasks.

In some instances, the possible source of the product fault issue is on the production side, for example, a product fault due to a fault with the equipment that produces the product. Therefore, the current common practice is to create a knowledge graph based on data from the production side, such as data from the MES and SAP system. The data from these systems is generally structured and stored in various relational databases such as Oracle, Impala, etc., making it easy for computers to extract information and map it to ontologies to create knowledge graphs.

However, in actual production, product fault problems potentially also originate from the design side, for example, product fault due to incorrect component dimensions or incorrect material labeling in the design. Moreover, product failures caused by the design side actually have a far more profound impact on the entire production process. Therefore, it is necessary to create knowledge graphs based on design-related data. However, data related to product design is generally semi-structured or unstructured, and it cannot be directly accessed by computers to acquire meaningful information like structured data. In some cases, design-related data may be stored in a semi-structured data format, for example, the Extensible Markup Language (XML) format, JSON format, or HyperText Markup Language (HTML) format. In other cases, design-related data may be stored in an unstructured data format, for example, CAD format, JPG format, any applicable image format, or PDF format.

To this end, the present disclosure proposes a method for product fault root cause analysis based on knowledge graphs, which is not solely dependent on data from the production side, but can further advantageously utilize multi-source heterogeneous data from the design side, expert experience, and the like, to create a knowledge graph to infer complete and deep potential fault occurrence paths in the event of product faults, providing a more comprehensive decision-making support for product fault root cause analysis. The method proposed for product fault root cause analysis based on knowledge graphs will be described in detail below. It should be understood by those skilled in the art that the present disclosure may be applicable to any production line or production process and is not limited to specific fields.

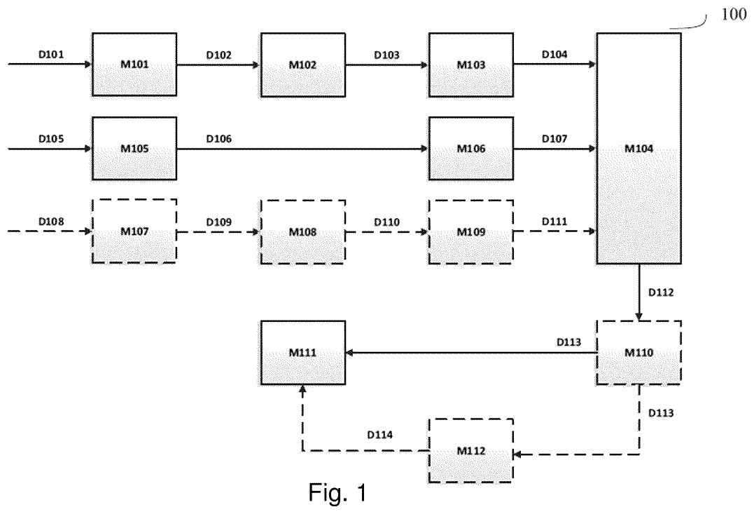

FIG. 1 shows a module and data flow diagram for product fault root cause analysis conducted based on a knowledge graph according to one example of the present disclosure, wherein the dotted boxes represent optional modules. The various modules provided by this example may be implemented in the form of software and/or hardware, and may be integrated into a computing device capable of executing this example, or may be distributed among a plurality of computing devices capable of executing this example.

Referring to FIG. 1, the product-associated design data D101 is acquired, and the design data D101 is entered and stored in an applicable format in a design data storage unit M101, wherein the design data D101 may be stored as semi-structured data and/or unstructured data.

In one example, the product-associated design data D101 may comprise product requirement documents, product assembly drawings, component design documents, component design drawings, circuit design documents, circuit schematics, design logs, and the like. Among these, the circuit design documents and design logs may be stored in either XML format or HTTP format, both of which have a semi-structured data structure. Among these, the product requirement documents and component design documents may be stored in any applicable office document or text format, and the product assembly drawings, component design drawings and circuit schematics may be stored in image formats such as CAD format and JPG format, or in PDF format. These formats have an unstructured data structure. The sources of design data described above are merely exemplary only and do not limit the scope of the present disclosure in any way.

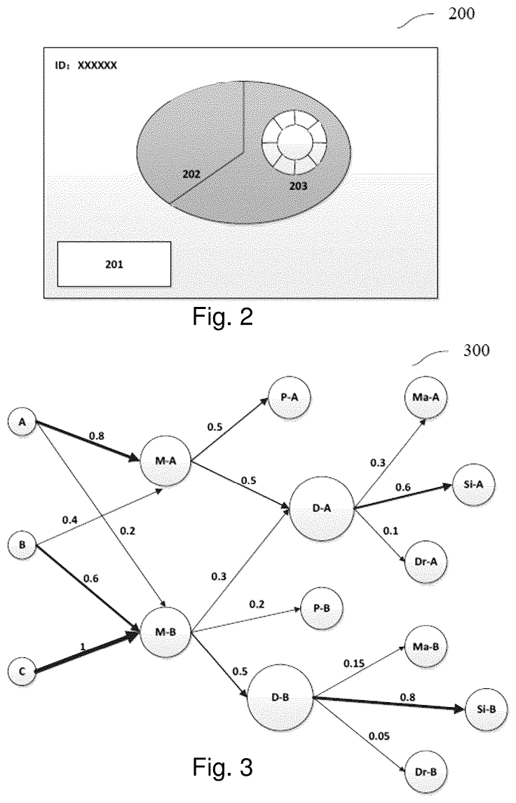

FIG. 2 shows an exemplary product component design drawing according to one example of the present disclosure. Referring to FIG. 2, the exemplary product component design drawing is labeled with the design drawing number ID in the upper left corner. The middle section shows the shape and dimensions of the component, while the box 201 in the bottom left corner generally contains textual annotations related to the design, and the boxes 202 and 203 in the middle generally annotate the component dimensions. For example, box 202 may annotate the axis dimensions of an elliptical component with numbers, while box 203 may annotate the diameter of a spherical component with numbers. As shown, design drawings generally comprise both graphical and numerical information, with the positions of the graphics, numbers, and text varying depending on the design drawing. Building a knowledge graph requires acquiring meaningful information that can be read by a computer from a vast amount of similar component design drawings, so additional processing is required.

With continued reference to FIG. 1, the semi-structured and/or unstructured design data D102 is fed into a design data preprocessing unit M102 for preprocessing to convert it into structured data D103.

In one example, when the design data D102 is semi-structured data, the design data preprocessing unit M102 performs an information extraction operation on the design data D102.

In one example, the information extraction operation comprises one or more of the following: entity extraction, relationship extraction, and attribute extraction. Therein, entities are recognized from the design data D102 through the entity extraction operation. For example, the entities “component 1”, “component 2”, and “component 3” may be recognized through the entity extraction operation based on the description “the shape of component 1 is elliptical, and component 1 includes component 2 and component 3”. Therein, entity relationships are recognized from the design data D102 through the relationship extraction operation. For example, the “inclusion” relationship of “component 1” with “component 2”, and “component 3” may be recognized through the relationship extraction operation based on the description “the shape of component 1 is elliptical, and component 1 includes component 2 and component 3”. Therein, entity attributes are recognized from the design data D102 through the entity extraction operation. For example, the “shape” attribute of “component 1” with a value of “elliptical” may be recognized through the attribute extraction operation based on the description “the shape of component 1 is elliptical, and component 1 includes component 2 and component 3”. In some examples, an attribute extraction operation may also be implemented as instances of a relationship extraction operation.

In one example, entity extraction may be implemented using one or more of the following: rule-based methods, such as regular matching, etc.; statistical model-based methods, for example, a hidden Markov model, a conditional Markov model, a maximum entropy model, and a conditional random field model, etc.; and deep learning-based methods, for example, methods based on convolutional neural networks, recurrent neural networks, and neural networks that introduce attention mechanisms, such as LSTM-CRF, LSTM-CNN-CRF, transformer, etc.

In one example, relationship extraction may be implemented using one or more of the following: template-based relationship extraction methods; supervised learning-based relationship extraction methods, for example, by converting relationship extraction into a classification problem and training models such as support vector machines and naïve Bayes classifiers; weak supervised learning-based relationship extraction methods, for example, the bootstrapping method.

In one example, entity extraction and relationship extraction are performed separately in sequence. In another example, entity extraction and relationship extraction are performed jointly, for example, by using methods such as BERT, LSTM-RNN, DGCNN, etc.

In one example, attribute extraction may be implemented using one or more of the following: unsupervised methods, for example, rule-based slot filling methods, clustering-based methods, etc.; dependent semi-supervised methods based on dependency relationships, for example, methods using the PageRank algorithm; sequence labeling methods based on deep learning, for example, a CRF model, BI-GRU+CRF model, etc.; attribute extraction methods based on meta-patterns, etc.

In one example, the information extraction operation may comprise one or more of the following tasks: word segmentation, word list lookup, syntactic analysis, corpus processing, named-entity recognition, terminology extraction, part-of-speech tagging, lexico-semantic role annotation, entity relationship recognition, and sequence labeling.

In another example, when the design data D102 is unstructured data, the design data preprocessing unit M102 has to perform an optical character recognition operation to the design data D102, to convert text in the design data D102 into a computer-readable text format, prior to performing information extraction on the design data D102. After the unstructured design data D102 is converted into a computer-readable text format, the information extraction operation may continue based on the description provided earlier.

In one example, the structured data D103 may be stored in a relational database. In further examples, the structured data D103 is organized in the form of design metadata having corresponding design drawing numbers, wherein the design drawing numbers may correspond to indices in a data table, and the design metadata may correspond to the headers of multiple data tables, wherein each data table is considered a class, with each row representing an instance or object of that class, and each column representing an attribute of that class. Furthermore, therein, the design metadata may be extracted from the design data D102 through an information extraction operation by the design data preprocessing unit M102, and the design metadata may correspond to the extracted entities, relationships, and/or attributes. For example, the design metadata may comprise one or more of the following: product name, product number, component quantity, component name, component number, component shape, component material, component dimensions, assembly sequence, etc.

With continued reference to FIG. 1, the structured data D103 is input into a design knowledge generation unit M103 to acquire design knowledge D104.

In one example, the design knowledge D104 may be acquired by converting the structured data D103 into an RDF format or RDFS format.

Specifically, the structured data D103 may be converted into an RDF format or RDFS triple format. For example, RDF or RDFS triples may organize the mapped data in a {subject-predicate-object} format. Also, for example, RDF or RDFS triples may organize the mapped data in a {subject-attribute-attribute value} format. Further, because the assembly sequence of the product components has a significant impact on the root cause analysis of faults, time sequence information may be added to RDF or RDFS triples to obtain RDF or RDFS quads.

In further examples, the design knowledge D104 may be acquired by mapping the structured data D103 to an ontology in an established ontology repository. In this case, the design knowledge D104 may be a knowledge graph constructed based on the design data D101.

The process of building the knowledge graph may comprise first developing an ontology based on product-associated design data. An ontology may generally be understood as a conceptual description of a specific field (for example, automotive parts production), and it can represent knowledge data that can be understood by those skilled in the art in terms of classes and relationships. A design-related ontology may be developed in a bottom-up manner based on product-associated design data. Various ontology development methods may be utilized to develop the aforementioned ontology, for example, methods such as CommonKADS, TOVE, IDEF5, Methontology, etc. The development of the ontology may be achieved using the Web Ontology Language (OWL). In addition, during the ontology development process, expert experience may be incorporated to further modify or refine the ontology in a top-down manner based on expert knowledge.

As previously described, the structured data D103 may be converted into the RDF triples or RDF quads formats, after which the RDF triples or RDF quads data may be integrated with the established OWL ontology to acquire the design knowledge D104. Specifically, R2RML (RDB to RDF Mapping Language) mapping can be used to map data fields in RDF triples or RDF quads to the created ontology. In addition, other mapping methods may be utilized, such as direct mapping, D2RQ, etc.

With continued reference to FIG. 1, the product-associated production data D105 is acquired, and the production data D105 is entered and stored in an applicable format in a production data storage unit M105, wherein the production data D105 may be stored as structured data.

In one example, the product-associated production data D105 may comprise any production-related records, for example, data from a factory, data from a production line, or data from production equipment, including data from an MES, data from an SAP system, production statistics (such as factory data, plant data, production line data, equipment data, etc.), etc. The production data D105 is generally structured data in a format that can be easily processed by a computer. For example, data from an MES generally has a standardized format: Machine={machine type, machine status . . . }. The production data D105 may be stored in relational databases, for example, Oracle, DB2, MySQL, Impala, etc. The sources of production data described above are merely exemplary and do not limit the scope of the present disclosure in any way.

With continued reference to FIG. 1, the structured data D106 is input into a production knowledge generation unit M106 to acquire production knowledge D107.

In one example, similar to the design knowledge D104, the production knowledge D107 may be acquired by converting the structured data D106 into an RDF format or RDFS format.

In further examples, similar to the design knowledge D104, the production knowledge D107 may be acquired by mapping the structured data D106 to an ontology in an established ontology repository. In this case, the production knowledge D107 may be a knowledge graph constructed based on the production data D105.

The process of building the knowledge graph may comprise first developing an ontology based on product-associated production data. An ontology may generally be understood as a conceptual description of a specific field (for example, automotive parts production), and it can represent knowledge data that can be understood by those skilled in the art in terms of classes and relationships. A production-related ontology may be developed in a bottom-up manner based on product-associated production data. Various ontology development methods may be utilized to develop the aforementioned ontology, for example, methods such as CommonKADS, TOVE, IDEF5, Methontology, etc. The development of the ontology may be achieved using the Web Ontology Language (OWL). In addition, during the ontology development process, expert experience may be incorporated to further modify or refine the ontology in a top-down manner based on expert knowledge.

For the process of acquiring the production knowledge D107 based on the structured data D106 using the production knowledge generation module M106, reference may be made to the description of the process for acquiring the design knowledge D104 based on the structured data D103, and will not be repeated herein.

In the actual product fault root cause analysis process, design data and production data more often reveal potential fault paths between products, components and production equipment. In contrast, expert experience can provide real fault paths from past product fault root cause analysis. Therefore, incorporating expert experience is also beneficial for conducting product fault root cause analysis.

With continued reference to FIG. 1, optionally, expert experience-associated expert data D108 is acquired, and the expert data D108 is entered and stored in an applicable format in an expert data storage unit M107.

In some cases, the expert data D108 may comprise: fault detection records, production equipment manuals, maintenance history documents, etc., wherein the expert data D108 may be stored as structured data, semi-structured data, and/or unstructured data. The sources of expert data described above are merely exemplary and do not limit the scope of the present disclosure in any way.

In some cases, expert knowledge D111 may be RDF triples or RDF quads data. In some cases, the expert knowledge D111 may be a knowledge graph constructed based on the expert data D108. For the process of acquiring the expert knowledge D111 based on the structured data D109 using the expert knowledge generation unit M109, reference may be made to the description of the process for acquiring the design knowledge D104 based on the structured data D103, and will not be repeated herein. For the process of acquiring the expert knowledge D111 based on the semi-structured data and/or unstructured data D109 using an expert data preprocessing unit M108 and the expert knowledge generation unit M109, reference may be made to the description of the process for acquiring the design knowledge D104 based on the semi-structured and/or unstructured data D102, and will not be repeated herein.

With continued reference to FIG. 1, the design knowledge D104 and the production knowledge D107, as well as the optional expert knowledge D111, are fed into the knowledge fusion unit M104 for knowledge fusion to produce the fused knowledge D112.

The goal of knowledge fusion is to integrate knowledge from various levels (such as the conceptual level and the data level). In one example, knowledge fusion may comprise one or more of the following processes: data preprocessing, chunking, load balancing, record linkage, result evaluation and/or result output.

In the case where the design knowledge D104, the production knowledge D107, and the optionally expert knowledge D111 are RDF triples or RDF quads, knowledge fusion aims to discover equivalent instances between data from different sources. In one example, knowledge fusion comprises one or more of the following tasks: data cleaning, entity alignment, entity matching, entity disambiguation, relationship deduplication, etc. In this case, the fused knowledge D112 is RDF triples or RDF quads data.

In the case where the design knowledge D104 and the production knowledge D107, as well as the optional expert knowledge D111, are knowledge graphs created based on the design data D101, the production data D105, and the expert data D108, respectively, knowledge fusion aims to discover equivalent instances, or concepts or attributes that exhibit equivalence or inclusion relationships across multiple knowledge graphs. In one example, knowledge fusion comprises one or more of the following tasks: data cleaning, ontology alignment, ontology matching, entity alignment, entity matching, entity disambiguation, relationship deduplication, etc. In this case, the fused knowledge D112 is a complete knowledge graph that combines the design knowledge D104, the production knowledge D107 and the expert knowledge D111 (optional).

In another example, during the knowledge fusion process, expert experience may be incorporated by other ways, thereby further modifying or refining the knowledge fusion process. For example, equivalent ontologies/entities, conflicting ontologies/entities, duplicate ontologies/entity relationships, and/or attributes that can be merged may be identified through expert annotation.

In another example, the knowledge data input into the knowledge fusion unit may comprise knowledge data from other sources in addition to data in the examples described above, including, but not limited to: procurement knowledge from procurement data, material knowledge from material data, and acceptance knowledge from acceptance data. The sources of expert described above are merely exemplary and do not limit the scope of the present disclosure in any way. Depending on whether the data from various sources is structured, semi-structured or unstructured data, similar processing can be performed with reference to the above descriptions for design data, production data and/or expert data to obtain corresponding knowledge data.

Generally, due to the sensitivity of various product-associated data, encryption is required when obtaining raw data to ensure system robustness, especially when the raw data is obtained in electronic form from cloud services such as the Azure cloud. For example, when obtaining production data from an MES or SAP system from the cloud, the raw data is usually downloaded in key-value pair format, and at least the sensitive data columns are encrypted.

With continued reference to FIG. 1, optionally, the structured data D112 is input into a knowledge graph generation unit M110 to construct a knowledge graph D113.

In one example, the fused knowledge data D112 may comprise the design knowledge D104, the production knowledge D107 and the expert knowledge D111. In further examples, the fused knowledge data D112 may comprise procurement knowledge, material knowledge, acceptance knowledge, etc. In the case where the fused knowledge D112 is RDF triples or RDF quads data, it is mapped to an ontology in the established ontology repository to construct the complete knowledge graph D113. With reference to the above description, the ontology repository may be constructed in a top-down and/or bottom-up manner based on various product-associated raw data. In one example, the established ontology may comprise one or more of the following ontologies: design ontology, product ontology, equipment ontology, material ontology, physical asset ontology, process segment ontology, expert ontology, procurement ontology, acceptance ontology, etc.

Through the method described above, the complete knowledge graph can integrate multi-source heterogeneous data from the design side, production side, and expert experience. This allows for the inference of more comprehensive and in-depth potential fault occurrence paths when a product fault occurs, providing more comprehensive decision-making support for product fault root cause analysis.

In one example, the constructed knowledge graph may be stored in a graph database, through which queries on entities, entity relationships, and/or entity attributes in the knowledge graph can be performed using query languages like SPARQL, thus providing support for product fault root cause analysis. In further examples, the constructed knowledge graph may be visualized. For example, entities from the knowledge graph D113 may be used as nodes, and the entity relationships may be used as connecting edges to generate a graph, wherein attributes may also be designed as entities, and the relationships between entities and entity attributes may be designed as entity relationships. Therefore, processing may be performed in a similar manner.

Further, the constructed knowledge graph may be utilized to provide more diverse applications. With continued reference to FIG. 1, the constructed knowledge data D113 is input into a knowledge graph application unit M111 to perform product fault root cause analysis tasks.

In one example, the knowledge graph application unit M111 may provide a product fault causal chain generation service. For example, the product fault causal chain generation service may visualize all potential fault root cause paths based on user queries regarding faulty products, components, or fault phenomena. In further examples, the knowledge graph application unit M111 may visualize all potential fault root cause paths based on the knowledge graphs stored in the graph database, and it may also calculate the weight for each connecting edge, wherein a higher weight indicates a higher probability of fault occurrence/frequency. In one example, the weight of each of the connecting edges is calculated based on one of degree centrality, eigenvector centrality, betweenness centrality, or closeness centrality.

FIG. 3 shows a causal chain diagram for product fault root cause analysis using a constructed knowledge graph according to one example of the present disclosure. As shown in FIG. 3, each point represents an entity, and each connecting edge represents an entity relationship. For example, node A represents product A, node M-A represents manufacturing plant A, node P-A represents production plant A, node D-A represents design document A, and reference numerals with suffix B are indicated in the same manner as reference numerals with suffix A; in the example in FIG. 3, the design document also comprises product/component attributes that are designed as entities, wherein “Ma” represents material, “Si” represents size, and “Dr” represents drawing. The existence of connecting edges between nodes indicates the presence of potential fault paths, with higher weights on the connecting edges indicating a higher probability/frequency of fault occurrence.

In one example, a depth-first search (DFS) may be performed in ascending order of the connecting edge weights until the true root cause of a fault is found. For example, to analyze the root cause of a fault for product B, firstly follow the connecting edge with a weight of 0.6 to the production plant M-B; if the production plant M-B is not the root cause of the failure, follow the connecting edge with a weight of 0.5 to the design document D-B; in order to determine whether the design document D-B is the root cause of the failure, it is necessary to check the dimensions, materials and drawings in the design document D-B in ascending order of weight; if the design document D-B is not the root cause of the failure, continue to check the design document D-A with a weight of 0.3. Follow a similar process until the exact root cause of the fault is found.

In one example, the knowledge graph application unit M111 may provide a product fault root cause search service. For example, a plurality of potential fault root cause nodes may be provided based on user queries regarding faulty products, components, or fault phenomena. In one example, the user may use the SPARQL language to perform queries. In one example, the returned fault root cause nodes may be sorted and filtered according to descending order based on the weights of the connected edges as described above.

In one example, the knowledge graph application unit M111 may provide a product fault root cause automatic generation service. For example, when a fault occurs on the production line, the knowledge graph application unit M111 is capable of providing the user with inferred root cause nodes about the product fault based on the identified fault. In one example, the user may be provided with a plurality of potential fault root cause nodes, which may be sorted and filtered according to descending order based on the weights of the connected edges as described above.

The use of product-associated multi-source heterogeneous data to construct a knowledge graph has been described above, and various applications related to product fault root cause analysis have been provided based on the constructed knowledge graph. On this basis, in order to further improve the fault root cause analysis capabilities of the constructed knowledge graph, the present disclosure also provides a method for training the constructed knowledge graph using a machine learning model.

With continued reference to FIG. 1, optionally, the constructed knowledge data D113 is input into a knowledge graph training unit M112 for training using a machine learning model.

In one example, the constructed knowledge graph D113 is input into a machine learning model, which is subjected to supervised training based on the output of the most likely fault paths or fault nodes. For example, the constructed knowledge graph D113 is input into a machine learning model in the form of a graph, wherein the nodes and edges of the knowledge graph may be individually converted into multi-dimensional vectors; the knowledge graph D113 may then output the most likely fault path or fault node, which may also be expressed as a multi-dimensional vector, for example, the most likely fault path or fault node may be screened by ascending order based on the weights of the connecting edges as described above. In one example, the machine learning model may be a graph neural network model, such as one or more of a graph convolutional network, a graph autoencoder, a graph generative network, a graph recurrent network, or a graph attention network.

During the training process, the machine learning model may use the actual fault paths or fault nodes as labels, and use the difference between the most likely fault paths or fault nodes outputted and the labels as the loss function. Minimizing this loss function enables the training of the knowledge graph D113. For example, the difference between the most likely fault paths or fault nodes outputted and the labels may be measured using methods such as cosine similarity, log-likelihood similarity, Euclidean distance, Manhattan distance, etc. Subsequently, the trained knowledge graph D114 is input into the knowledge graph application unit M111 to perform product fault root cause analysis tasks.

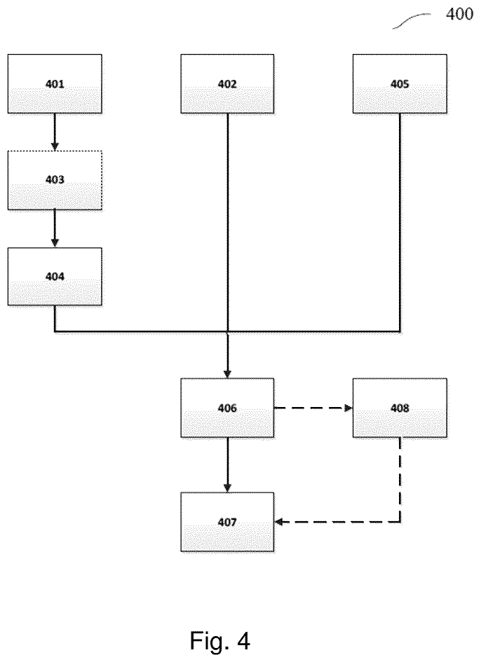

FIG. 4 shows a flowchart for product fault root cause analysis conducted based on a knowledge graph according to one example of the present disclosure, wherein the dotted boxes represent optional operations. The various steps provided in this example may be implemented by one or a plurality of devices with computing capabilities by way of software and/or hardware.

In step S401, product-associated design data may be acquired, wherein the design data comprises semi-structured data and/or unstructured data. Therein, the operation in step S401 may, for example, be implemented by the design data storage unit M101, as described with reference to FIG. 1.

In one example, the design data is from one or more of the following: product requirement documents, product assembly drawings, component design documents, component design drawings, circuit design documents, circuit schematics and design logs. For example, the circuit design documents and design logs may be stored in either XML format or HTTP format, both of which have a semi-structured data structure. For example, the product requirement documents and component design documents may be stored in any applicable office document or text format, and the product assembly drawings, component design drawings and circuit schematics may be stored in image formats such as CAD format and JPG format, or in PDF format. These formats have an unstructured data structure.

In step S402, product-associated production data may be acquired, wherein the production data comprises structured data. Therein, the operation in step S402 may, for example, be implemented by the production data storage unit M105, as described with reference to FIG. 1.

In one example, the production data is from one or more of the following: the MES, SAP system, and production statistics. Therein, production statistics may comprise production records from the plant, production records from the plant, production records from the production line, and/or production records from the equipment.

In step S403, optionally, an optical character recognition operation may be applied to the design data to convert text in the design data into a computer-readable text format. Therein, the operation in step S403 may, for example, be implemented by the design data preprocessing unit M102, as described with reference to FIG. 1.

In step S404, information extraction may be performed on the design data to acquire structured design data. Therein, the operation in step S403 may, for example, be implemented by the design data preprocessing unit M102, as described with reference to FIG. 1.

In one example, the information extraction performed on the design data comprises performing entity extraction and relationship extraction on the design data to identify entities and entity relationships entities from the design data. For example, entity extraction may be implemented using one or more of the following: rule-based methods, such as regular matching, etc.; statistical model-based methods, for example, a hidden Markov model, a conditional Markov model, a maximum entropy model, and a conditional random field model, etc.; and deep learning-based methods, for example, methods based on convolutional neural networks, recurrent neural networks, and neural networks that introduce attention mechanisms, such as LSTM-CRF, LSTM-CNN-CRF, transformer, etc. For example, relationship extraction may be implemented using one or more of the following: template-based relationship extraction methods; supervised learning-based relationship extraction methods, for example, by converting relationship extraction into a classification problem and training models such as support vector machines and naïve Bayes classifiers; weak supervised learning-based relationship extraction methods, for example, the bootstrapping method.

In one example, entity extraction and relationship extraction are performed separately in sequence. In another example, entity extraction and relationship extraction are performed jointly, for example, by using methods such as BERT, LSTM-RNN, DGCNN, etc.

In further examples, the information extraction performed on the design data further comprises performing attribute extraction on the design data to identify the attributes of entities from the design data. For example, attribute extraction may be implemented using one or more of the following: unsupervised methods, for example, rule-based slot filling methods, clustering-based methods, etc.; dependent semi-supervised methods based on dependency relationships, for example, methods using the PageRank algorithm; sequence labeling methods based on deep learning, for example, a CRF model, BI-GRU+CRF model, etc.; attribute extraction methods based on meta-patterns, etc. For another example, an attribute extraction operation may be implemented as instances of a relationship extraction operation.

In one example, the information extraction performed on the design data comprises one or more of the following tasks: word segmentation, word list lookup, syntactic analysis, corpus processing, named-entity recognition, terminology extraction, part-of-speech tagging, lexico-semantic role annotation, entity relationship recognition, and sequence labeling.

In one example, the structured design data is organized in the form of design metadata with corresponding design drawing numbers. Wherein, the design drawing numbers may correspond to indices in a data table, and the design metadata may correspond to the headers of multiple data tables, wherein each data table is considered a class, with each row representing an instance or object of that class, and each column representing an attribute of that class. Furthermore, therein, the design metadata may be extracted from the design data through an information extraction operation, and the design metadata may correspond to the extracted entities, relationships, and/or attributes. For example, the design metadata may comprise one or more of the following: product name, product number, component quantity, component name, component number, component shape, component material, component dimensions, assembly sequence, etc.

Optionally, in step S405, one or more of expert experience, procurement data, material data and acceptance data may also be acquired. Therein, the operation in step S405 may, for example, be implemented by the expert experience storage unit M107, as described with reference to FIG. 1. Therein, the data from various sources is structured, semi-structured or unstructured data, and processing can be performed with reference to the above relevant descriptions.

In step S406, knowledge fusion of knowledge generated separately based on the production data and the structured design data may be performed to construct the target knowledge graph. Optionally, knowledge fusion of data generated based on one or more of expert experience, procurement data, material data and acceptance data may be further performed to construct the target knowledge graph. Therein, the operation in step S406 may, for example, be implemented by the design knowledge generation unit M103, the production knowledge generation unit M106 and the expert knowledge generation unit M109, as described with reference to FIG. 1. Additionally, the operation in step S406 may, for example, be implemented by the knowledge fusion unit M104, as described with reference to FIG. 1. Optionally, the operation in step S406 may, for example, be implemented by the knowledge graph generation unit M110, as described with reference to FIG. 1.

In one example, the production data and the structured design data may be separately converted into one of the following formats: the RDF triple format, RDF quad format with time information, RDFS format, or RDFS quad format with time information, to acquire knowledge generated based on the production data and the structured design data.

In further examples, an ontology repository may be established based at least on the design data and the production data (optionally, one or more of expert experience, procurement data, material data, and acceptance data), with the ontology repository comprising a plurality of ontologies; subsequently, the production data and structured design data in RDF or RDFS triple format, or RDF or RDFS quad format is mapped to the plurality of ontologies to acquire the knowledge generated based on the production data and structured design data. For example, an ontology may be developed in a bottom-up and/or top-down manner based on product-associated raw data. For example, the ontology repository comprises one or more of the following: design ontology, product ontology, equipment ontology, material ontology, physical asset ontology, process segment ontology, expert ontology, procurement ontology, and acceptance ontology.

In one example, where the knowledge based on the production data and the structured design data is RDF triples or RDF quads data, the knowledge fusion comprises one or more of the following tasks: data cleaning, entity alignment, entity matching, entity disambiguation, relationship deduplication, etc. In this example, the fused knowledge is mapped to the plurality of ontologies to construct the target knowledge graph.

In another example, where the knowledge based on the production data and the structured design data is mapped to the plurality of ontologies, the knowledge fusion comprises one or more of the following tasks: data cleaning, ontology alignment, ontology matching, entity alignment, entity matching, entity disambiguation, relationship deduplication, etc. In this example, the fused knowledge is the target knowledge graph.

In one optional example, similar processing based on one or more of expert experience, procurement data, material data and acceptance data may be further performed with reference to the above descriptions to construct the target knowledge graph.

In further examples, equivalent ontologies/entities, conflicting ontologies/entities, duplicate ontologies/entity relationships, and/or attributes that can be merged may be identified through expert annotation during knowledge fusion.

In step S407, product fault root cause analysis tasks may be performed based on the target knowledge graph. Therein, the operation in step S405 may, for example, be implemented by the knowledge graph application unit M111, as described with reference to FIG. 1.

In one example, the product fault root cause analysis tasks performed based on the target knowledge graph comprises: taking at least the entities in the target knowledge graph as nodes and the relationship between the entities as connecting edges, calculating the weight of each connecting edge; further performing the product fault root cause analysis tasks using DFS based on the weight of each connecting edge. For example, the weight of each of the connecting edges may be calculated based on one of degree centrality, eigenvector centrality, betweenness centrality, or closeness centrality. For example, the product fault root cause analysis tasks comprise a product fault causal chain generation service, a product fault root cause search service, and/or a product fault root cause automatic generation service.

Optionally, in step S408, the target knowledge graph may be trained using a machine learning model, and the product fault root cause analysis task of step S407 may subsequently be performed based on the trained target knowledge graph. Therein, the operation in step S408 may, for example, be implemented by the knowledge graph training unit M112, as described with reference to FIG. 1.

In one example, training the target knowledge graph with a machine learning model may comprise: taking at least the entities in the target knowledge graph as nodes, using the entity relationships as connecting edges to generate the graph; representing the nodes and connecting edges as vectors and training the target knowledge graph using a graph neural network model. For example, the graph neural network model may be one or more of a graph convolutional network, a graph autoencoder, a graph generative network, a graph recurrent network, or a graph attention network.

In one example, training the target knowledge graph with a machine learning model may comprise: using the difference between the most likely fault paths or fault nodes outputted by the target knowledge graph and the actual fault paths or fault nodes as the loss function, and implementing the training of the target knowledge graph by minimizing the loss function. For example, the difference between the most likely fault paths or fault nodes outputted and the labels may be measured using methods such as cosine similarity, log-likelihood similarity, Euclidean distance, Manhattan distance, etc.

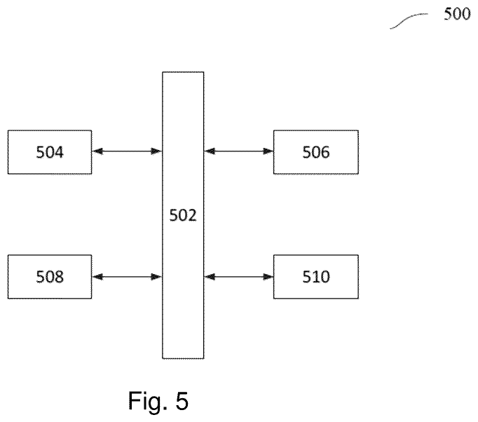

FIG. 5 shows a block diagram of a device capable of conducting product fault root cause analysis based on a knowledge graph according to one example of the present disclosure.

An exemplary computing device 500 comprises an internal communication bus 502 and a processor 504 (e.g., a central processing unit (CPU)) connected to the internal communication bus 502, wherein the processor 504 is used for executing instructions stored in a memory 506 to implement the method of product fault root cause analysis based on the knowledge graph detailed above. The memory 506 is capable of physically embodying computer program instructions and data, and may comprise various forms of memory, such as semiconductor memory devices such as EPROM, EEPROM, and flash memory devices; magnetic disks such as internal hard disks and removable disks; magneto-optical disks; and CD-ROM disks, etc. The computing device 500 may also comprise an input/output (I/O) interface 508 such that various I/O devices (e.g., cursor control devices such as mice, keyboards, etc.) may be coupled to the computing device 500 via the I/O interface 508 to allow the user to apply various commands and input data. The computing device 500 may also comprise a display unit 510 for displaying a graphical user interface.

The computer program may comprise instructions executable by a computer. These instructions are used to enable the processor 504 of the computing device 500 to execute the method of product fault root cause analysis based on the knowledge graph according to the present disclosure. The program may be recorded on any data storage medium, including a memory. For example, the program may be implemented in digital electronic circuits or by using computer hardware, firmware, software, or a combination thereof. The process/method steps described in the present disclosure can be performed by a programmable processor executing program instructions to operate on input data and generate output to perform the method steps, processes and operations.

It is to be noted that “based on” in the description herein means “based on at least” and not “based only”. In addition to the content described herein, various modifications can be made to the examples and implementations of the present disclosure without departing from the scope of the examples and implementations of the present disclosure. Therefore, the description and examples herein should be interpreted as illustrative and not restrictive. The scope of the present disclosure should only be determined by reference to the patent claims.

What is claimed is:

1. A method for product fault root cause analysis based on knowledge graphs, comprising:
acquiring product-associated design data, wherein the design data comprises semi-structured data and/or unstructured data;
acquiring product-associated production data, wherein the production data comprises structured data;
performing information extraction on the design data to acquire structured design data;
performing a knowledge fusion of knowledge generated separately based on the production data and the structured design data to construct a target knowledge graph; and
performing product fault root cause analysis tasks based on the target knowledge graph.

2. The method according to claim 1, further comprising:
generating expert knowledge based on expert experience; and
performing a knowledge fusion of knowledge generated separately based on the production data and the structured design data with the expert knowledge to construct the target knowledge graph.

3. The method according to claim 1, further comprising:
applying an optical character recognition operation to the design data, to convert text in the design data into a computer-readable text format, prior to performing information extraction on the design data.

4. The method according to claim 1, with the information extraction performed on the design data comprising:
performing entity extraction and relationship extraction on the design data to identify entities and entity relationships entities from the design data.

5. The method according to claim 4, with the information extraction performed on the design data comprising:
performing attribute extraction on the design data to identify the attributes of entities from the design data.

6. The method according to claim 1, with the information extraction performed on the design data comprising one or more of the following tasks: word segmentation, word list lookup, syntactic analysis, corpus processing, named-entity recognition, terminology extraction, part-of-speech tagging, lexico-semantic role annotation, entity relationship recognition, and sequence labeling.

7. The method according to claim 1, wherein the structured design data is organized in the form of design metadata with corresponding design drawing numbers.

8. The method according to claim 7, wherein the design metadata corresponds to one or more of the following acquired by performing the information extraction: entities, entity relationships, attributes of the entities; and/or
the design metadata comprises one or more of the following: product name, product number, component quantity, component name, component number, component shape, component material, component dimensions, and assembly sequence.

9. The method according to claim 1, further comprising:
converting the production data and the structured design data separately into one of the following formats: the Resource Description Framework (RDF) triple format, RDF quad format with time information, RDFS format, or RDFS quad format with time information, to acquire knowledge generated separately based on the production data and the structured design data.

10. The method according to claim 9, further including:
establishing an ontology repository comprising a plurality of ontologies based at least on the design data and the production data; and
mapping the production data and structured design data in RDF or RDFS triple format, or RDF or RDFS quad format, to the plurality of ontologies to acquire the knowledge generated separately based on the production data and structured design data.

11. The method according to claim 10, wherein the ontology repository comprises one or more of the following: design ontology, product ontology, equipment ontology, material ontology, physical asset ontology, process segment ontology, expert ontology, procurement ontology, and acceptance ontology.

12. The method according to claim 1, wherein the design data is from one or more of the following: product requirement documents, product assembly drawings, component design documents, component design drawings, circuit design documents, circuit schematics and design logs.

13. The method according to claim 1, wherein the production data is from one or more of the following: the manufacturing execution system (MES), SAP system, and production statistics.

14. The method according to claim 1, with the product fault root cause analysis performed based on the target knowledge graph comprising:
taking at least the entities in the target knowledge graph as nodes and the relationship between the entities as connecting edges, calculating the weight of each connecting edge; and
further executing product fault root cause analysis tasks using a depth-first search based on the weight of each of the connecting edges.

15. The method according to claim 14, wherein the weight of each of the connecting edges is calculated based on one of degree centrality, eigenvector centrality, betweenness centrality, or closeness centrality.

16. The method according to claim 1, further comprising:
taking at least the entities in the target knowledge graph as nodes, using the entity relationships as connecting edges to generate the graph;
expressing the nodes and connecting edges as vectors and training the target knowledge graph with a graph neural network model; and
performing the product fault root cause analysis tasks based on the trained target knowledge graph.

17. The method according to claim 16, wherein the graph neural network model comprises one of the following: graph convolutional networks, graph autoencoders, graph generative networks, graph recurrent networks, or graph attention networks.

18. A system for product fault root cause analysis based on knowledge graphs, comprising:
a memory; and
a processor which is coupled to the memory, with the processor configured to cause one or more units to execute the method according to claim 1.

19. A computer-readable medium storing a computer program comprising instructions, that, when executed by the processor, cause one or more units to execute the method according to claim 1.
